(19) United States
(12) Patent Application Publication
(10) Pub. No.: US 2025/0157928 A1
(43) Pub. Date: May 15, 2025

(54) STACKED FET POWER DELIVERY NETWORK FORMATION

(71) Applicant: INTERNATIONAL BUSINESS MACHINES CORPORATION, ARMONK, NY (US)

(72) Inventors: Ruilong Xie, Niskayuna, NY (US); Christopher J. Penny, Saratoga Springs, NY (US); Hosadurga Shobha, Niskayuna, NY (US); Koichi Motoyama, Clifton Park, NY (US); Kisik Choi, Watervliet, NY (US); Gideon Oyibo, Rensselaer, NY (US); Tao Li, Slingerlands, NY (US); John Christopher Arnold, North Chatham, NY (US); Chanro Park, Clifton Park, NY (US)

(21) Appl. No.: 18/510,596

(22) Filed: Nov. 15, 2023

(51) Int. Cl. H01L 23/528; H01L 21/822; H01L 21/8238; H01L 27/092; H01L 29/06; H01L 29/417; H01L 29/423; H01L 29/66; H01L 29/775

(52) U.S. Cl. CPC H01L 23/5286; H10D 30/014; H10D 30/43; H10D 30/6729; H10D 30/6735; H10D 62/121; H10D 84/0186; H10D 84/038; H10D 84/856; H10D 88/01

(57) ABSTRACT

A semiconductor device includes a top transistor stacked over a bottom transistor, a backside contact connected to a source/drain region of the bottom transistor, and a via connecting a source/drain region of the top transistor to a backside power rail (BPR). The backside contact has a T-shape profile both in a first direction and in a second direction, which is orthogonal to the first direction.

### BACKGROUND

### Technical Field

The present disclosure generally relates to transistors, and more particularly, to power delivery network formation in transistor structure, and methods of creation thereof.

### Description of the Related Art

Backside contacts provide a way to establish electrical connections with the backside or substrate of a transistor and enable efficient signal transmission, improved device performance, and enhanced manufacturing processes. In a typical transistor structure, the backside or substrate region is distinct from the active region where the transistor's channel and source/drain regions are located. The electrical connection established by the backside contacts provides a pathway for electrical signals, current, and voltage to flow, allowing communication between different components of an integrated circuit.

### SUMMARY

According to an embodiment, a semiconductor device includes a top transistor stacked over a bottom transistor, a backside contact connected to a source/drain region of the bottom transistor, and a via connecting a source/drain region of the top transistor to a backside power rail (BPR). The backside contact has a T-shape profile.

In some embodiments, which can be combined with the previous embodiment, the backside contact has a T-shape profile through both a first direction and a second direction. The first direction is orthogonal to the second direction.

In some embodiments, which can be combined with one or more previous embodiments, the semiconductor device includes a dielectric spacer over sidewalls of a vertical section of the backside contact.

In some embodiments, which can be combined with one or more previous embodiments, the dielectric spacer isolates the backside contact from the BPR.

In some embodiments, which can be combined with one or more previous embodiments, a top portion of the backside contact is isolated from a gate region by a bottom dielectric isolation (BDI).

In some embodiments, which can be combined with one or more previous embodiments, a source/drain region of the top transistor is connected to a back end of line (BEOL) through a first contact.

In some embodiments, which can be combined with one or more previous embodiments, the via is in contact with the first contact.

According to another embodiment, a method for forming a semiconductor device includes forming a top transistor stacked over a bottom transistor, forming a sacrificial placeholder below a source/drain region of the bottom transistor, removing a substrate below the bottom transistor, depositing additional sacrificial placeholder material to increase dimensions of the sacrificial placeholder in a first direction, forming a backside contact connected to a source/drain region of the bottom transistor, and forming a via connecting a source/drain region of the top transistor to a backside power rail (BPR).

In some embodiments, which can be combined with the previous embodiment, the backside contact has a T-shape profile through a first direction and a second direction. The first direction is orthogonal to the second direction.

In some embodiments, which can be combined with one or more previous embodiments, the method includes forming a dielectric spacer over sidewalls of a vertical section of the backside contact.

In some embodiments, which can be combined with one or more previous embodiments, the method includes connecting a source/drain region of the top transistor to the BPR by the via.

In some embodiments, which can be combined with one or more previous embodiments, the method includes isolating a top portion of the backside contact from a gate region by a bottom dielectric isolation (BDI).

In some embodiments, which can be combined with one or more previous embodiments, the method includes isolating the backside contact from the BPR by the dielectric spacer.

In some embodiments, which can be combined with one or more previous embodiments, the method includes connecting a source/drain region of the top transistor to a back end of line (BEOL) through a first contact.

In some embodiments, which can be combined with one or more previous embodiments, the method includes connecting a top portion of the via to the first contact.

According to yet another embodiment, a semiconductor device includes a top transistor stacked over a bottom transistor. A backside contact is connected to a source/drain region of the bottom transistor, and the backside contact has a T-shape profile through both a first direction and a second direction. The first direction is orthogonal to the second direction.

In some embodiments, which can be combined with the previous embodiment, the semiconductor device includes a dielectric spacer over sidewalls of a vertical section of the backside contact.

In some embodiments, which can be combined with one or more previous embodiments, the semiconductor device includes a via connecting a source/drain region of the top transistor to a backside power rail (BPR). The dielectric spacer isolates the backside contact from the BPR.

In some embodiments, which can be combined with one or more previous embodiments, a top portion of the backside contact is isolated from a gate region by a bottom dielectric isolation (BDI).

In some embodiments, which can be combined with one or more previous embodiments, the source/drain region of the top transistor is connected to a back end of line (BEOL) through a first contact, and the first contact is in contact with the via.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate a semiconductor device, in accordance with some embodiments.

FIG. 1D illustrates a top view of a semiconductor device, in accordance with some embodiments.

FIGS. 2A-2C illustrate side views of different respective cross-sections of a semiconductor device after the processing of the front end of line (FEOL), in accordance with some embodiments.

FIGS. 3A-3C illustrate side views of different respective cross-sections of a semiconductor device after the substrate removal, in accordance with some embodiments.

FIGS. 4A-4C illustrate side views of different respective cross-sections of a semiconductor device after the removal of the etch stop layer, in accordance with some embodiments.

FIGS. 5A-5C illustrate side views of different respective cross-sections of a semiconductor device after growing the SiGe layer, in accordance with some embodiments.

FIGS. 6A-6C illustrate side views of different respective cross-sections of a semiconductor device after the deposition of the interlayer dielectric (ILD), in accordance with some embodiments.

FIGS. 7A-7C illustrate side views of different respective cross-sections of a semiconductor device after the removal of the placeholder, in accordance with some embodiments.

FIGS. 8A-8C illustrate side views of different respective cross-sections of a semiconductor device after the metallization of the backside contact, in accordance with some embodiments.

FIGS. 9A-9C illustrate side views of different respective cross-sections of a semiconductor device after the recession of the backside contact, in accordance with some embodiments.

FIGS. 10A-10C illustrate side views of different respective cross-sections of a semiconductor device after the formation of the dielectric spacer, in accordance with some embodiments.

FIGS. 11A-11C illustrate side views of different respective cross-sections of a semiconductor device after selectively growing the metal, in accordance with some embodiments.

FIGS. 12A-12C illustrate side views of different respective cross-sections of a semiconductor device after the formation of the backside metal, in accordance with some embodiments.

FIGS. 13A-13C illustrate side views of different respective cross-sections of a semiconductor device after the formation of the backside interconnect, in accordance with some embodiments.

FIG. 14 illustrates a block diagram of different respective cross-sections of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to stacked field-effect transistors (FET), which are fundamental electronic devices that have revolutionized the field of electronics and how various elements of the transistors are electrically connected. The stacked FET is a type of transistor architecture that offers improved functionality and benefits in integrated circuit (IC) design. The stacked FET involves stacking multiple FETs on top of each other, allowing for enhanced performance and increased integration density.

Stacked FETs are used in semiconductor technologies to increase transistor density and improve the performance of ICs. FETs are vertically aligned on top of each other, sharing a common substrate. Each FET within the stack typically has its own gate, source, and drain regions. In such FETs, the ever-shrinking dimensions of the semiconductor device's components may cause an unintended electrical connection or short circuit between the backside contact of the source/drain region and the backside metal in the stacked structure. This problem can lead to various performance and reliability issues within the semiconductor device. This short circuit can result from defects in the insulating layers, misalignment during manufacturing, or other issues. Such a short circuit between the backside contact and a backside metal in a stacked FET structure can interfere with the intended electrical behavior of the FETs in the stack and lead to erratic or incorrect operation of the transistors and the integrated circuit as a whole. Unintended paths for electrical current can increase leakage current within the device, which can result in higher power consumption and potential overheating. Further, short circuits can disrupt signal paths, leading to degradation in signal integrity and potentially causing incorrect logic levels or data corruption. Over time, short circuits can contribute to device degradation and reduced reliability, potentially leading to premature failure of the integrated circuit.

To tackle the above-mentioned issues and others, disclosed is a semiconductor device with stacked FETs that utilizes an insulated backside contact to avoid backside contact-backside metal shorting. To that end, portions of the backside metal, that are in contact with the top source/drain region through a via and a top source/drain contact, are isolated from direct contact with the backside contact by forming an insulating layer on the side walls of the backside contact. Such electrically isolated backside contact ensures that backside contact-backside metal shorting is avoided.

Accordingly, the teachings herein provide methods and systems of semiconductor device formation with an insulated backside contact. The techniques described herein may be implemented in a number of ways. Example implementations are provided below with reference to the following figures.

Example Semiconductor Device with Insulated Backside Contact Structure

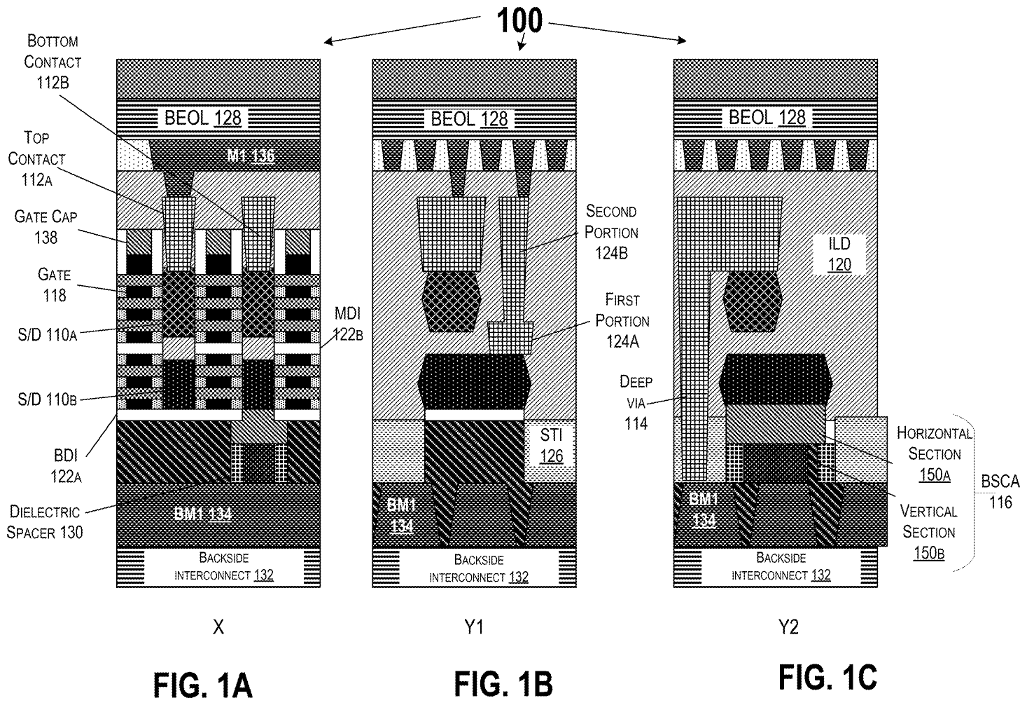

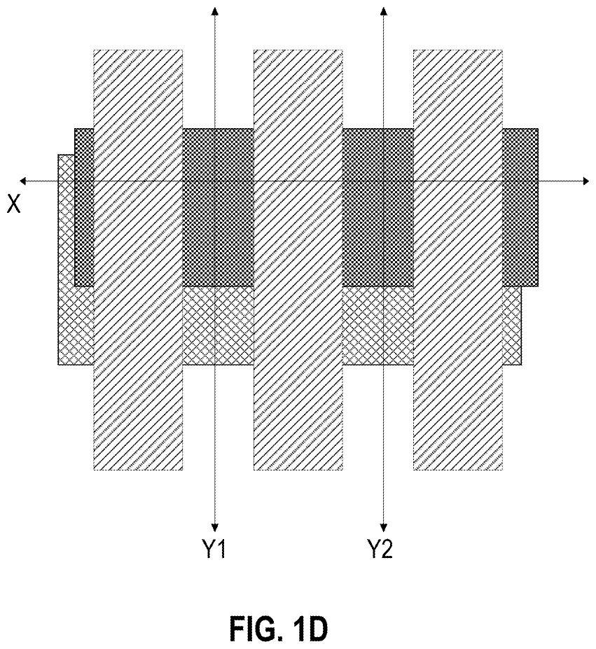

Reference now is made to FIGS. 1A-1C, which are simplified cross-section views of a semiconductor device 100, consistent with an illustrative embodiment. FIG. 1D depicts a top view of the semiconductor device 100. For example, FIG. 1A, and other figures denoted by A, illustrate a X cross-section of the semiconductor device, FIG. 1B, and other figures denoted by B, illustrate a Y1 cross-section of the semiconductor device and FIG. 1C, and other figures denoted by C, illustrate a Y2 cross-section of the semiconductor device.

In various embodiments, the semiconductor device 100 is a stacked FET that leverages the vertical dimension of the semiconductor device 100 to increase the number of active devices within a given area. This way, instead of relying solely on lateral scaling, where semiconductor devices are shrunk in size on the semiconductor substrate, stacking FETs vertically can enable the incorporation of multiple layers of semiconductor devices. This arrangement enables more complex circuitry and advanced functionality.

In several embodiments, the stacked FET structure of the semiconductor device 100 can enable higher integration densities by utilizing the vertical dimension of the semiconductor device 100. In such embodiments, instead of relying solely on lateral scaling, which has its limits, stacking FETs on the semiconductor device 100 allows for increased transistor count within a given chip area. This increased transistor count enables the integration of more complex circuits, larger memory arrays, and other functional blocks, enhancing the capabilities of the semiconductor device 100.

The disclosed semiconductor device 100 can include a top source/drain region 110A, a bottom source/drain region 110B, a top contact 112A, a bottom contact 112B, a via 114, a backside contact, BSCA, 116, a gate region 118, an interlayer dielectric, ILD, 120, a bottom dielectric isolation, BDI, 122A, a middle dialectic isolation, MDI, 122B, a shallow trench isolation 126, a back end of line, BEOL 128, a dielectric spacer 130, a backside interconnect 132, a backside metal layer, BM1 134, a first metal layer, M1 track 136, and a gate cap 138. In several embodiments, the top source/drain region 110A is located on a top transistor, and the bottom source/drain region 110B is located on a bottom transistor. In such an embodiment, the top transistor is stacked over the bottom transistor.

Generally, the top source/drain region 110A and the bottom source/drain region 110B are two salient components that play relevant roles in the semiconductor device's operation. In various embodiments, the top source/drain region 110A and the bottom source/drain region 110B are regions within the semiconductor material, e.g., the semiconductor device 100, where the current flows in and out of the semiconductor device 100. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The top contact 112A, located over the top source/drain region 110A, establishes a connection between the top source/drain region 110A and the BEOL 128 via the M1 track 136. The via 114, which is vertically extended from the top contact 112A to the BM1 134, establishes a connection between the top source/drain region 110A to the BM1 134. It should be noted that the BM1 134 can be a backside power rail (BPR). The top contact 112A ensures efficient electrical routing and connectivity within the semiconductor device 100. The fabrication of the top contact 112A can involve lithography and etching processes to define the contact area. The top contact 112A can be made using conductive materials such as a silicide liner, e.g., Ni, Ti, NiPt, an adhesion metal layer, e.g., TiN and conductive metal fill material, e.g., tungsten (W), Co, or Ru.

The bottom contact 112B, located over the bottom source/drain region 110B, establishes a connection between the second source/drain region 110B and the BEOL 128 via the M1 track 136. The bottom contact 112B can include a first portion 124A located over the bottom source/drain region 110B and a second portion 124B. The second portion 124B can be vertically extended from the first portion 124A to the M1 track 136. The bottom contact 112B ensures efficient electrical routing and connectivity within the semiconductor device 100. The fabrication of the bottom contact 112B can involve lithography and etching processes to define the contact area. The bottom contact 112B can be made using conductive materials such as a silicide liner, e.g., Ni, Ti, NiPt, an adhesion metal layer, e.g., TiN and conductive metal fill material, e.g., tungsten (W), Co, or Ru.

The BSCA 116 is a region on the backside of the semiconductor device 100 where electrical connections are made. By establishing the electrical contacts, the BSCA 116 ensures the proper functioning of the semiconductor device 100 and facilitates electrical signal transmission.

The BSCA 116 can serve as a thermal interface between the semiconductor device 100 and a heat sink or other cooling mechanisms. By establishing direct contact with the substrate, the BSCA 116 can conduct the heat away from the semiconductor device 100, and contribute to improved thermal dissipation. In some embodiments, the BSCA 116 can help mitigate parasitic effects, such as substrate coupling or substrate noise, from the semiconductor device 100. In further embodiments, the BSCA 116 can allow for increased integration density in the semiconductor device 100. In an embodiment, the BSCA 116 connects, i.e., wires, the bottom source/drain region 110B to the backside interconnect 132.

In some embodiments, the BSCA 116 can have a T-shape profile. The T-shape profile can be in both the X-cross section and the Y-cross section, which are orthogonal to each other, and can include a horizontal section 150a extended below the bottom source/drain region 110B and a vertical section 150b extended vertically from the horizontal section 150a to the BM1 134. In some embodiments, the width of the horizontal section 150a is larger than the width of the bottom source/drain region 110B. In some embodiments, the dielectric spacer 130 is formed over the sidewalls of the vertical section 150b of the BSCA 116. The dielectric spacer 130 can isolate, i.e., separate, the BSCA 116 from direct contact with the first contact 112A and the portions of the BPR or the BM1 134 that are connected to the first contact 112A. Thus, the dielectric spacer 130 can ensure that the BSCA 116 and the first contact 112A do not interfere with each other's operation. Additionally, the dielectric spacer 130 can be a non-conductive, i.e., insulating, layer that can be made from materials such as silicon dioxide (SiO2) or silicon nitride (Si3N4).

In various embodiments, the gate region 118 serves as control elements that regulate the flow of current through the semiconductor device 100. The gate region 118 can be composed of a conductive material. The gate region 118 can control the flow of electric current between the source and drain regions. In some embodiments, by applying a voltage to the gate, the channel region's conductivity is modulated, allowing the semiconductor device 100 to either allow or block the flow of current, which in turn enables the semiconductor device 100 to act as an electronic switch or amplifier. The gate voltage can determine whether the semiconductor device 100 is in an “on” or “off” state. When the gate voltage is below a certain threshold, the semiconductor device 100 is in the “off” state, and the current flow between the source and drain is effectively blocked. On the other hand, when the gate voltage exceeds the threshold, the semiconductor device 100 enters the “on” state, allowing current to flow through the channel region. In addition to acting as a switch, modulating the gate voltage can enable the gate region 118 to control the current flowing through the channel region, resulting in amplified output signals.

In an embodiment, the gate region 118 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate region 118, along with other semiconductor device components, can facilitate the miniaturization and integration of electronic circuits. The ability to control the channel region's conductivity through the gate voltage allows for compact and highly efficient circuit designs.

The ILD 120 can be a layer of insulating material to electrically isolate and provide mechanical support between different layers of conducting and active components. The ILD 120 can enable efficient signal transmission, reduce crosstalk, and ensure the proper functioning of the semiconductor device 100. In an embodiment, the ILD 120 can electrically isolate adjacent conducting layers or active components in the semiconductor device 100. By providing insulation between different layers, the ILD 120 can prevent electrical shorts, reduce (e.g., minimize) leakage current, and ensure that signals are directed only along the desired pathways. In some embodiments, the ILD 120 can help reduce parasitic capacitance between adjacent metal interconnects or active devices and provide mechanical support to the semiconductor device's structure.

The BDI 122A can electrically isolate individual components in the semiconductor device 100, and provide electrical isolation between each of the FETs in the stacked FET. That is, the BDI 122A can ensure that the operation of one component does not interfere with the operation of the others. By using a dielectric layer, which is an insulating layer that does not conduct electricity, the BDI 122A effectively prevents electrical crosstalk between different components and allows each one to operate independently. Further, by electrically isolating each transistor from the other, the BDI 122A can reduce the potential for crosstalk, which is the unwanted transfer of signals between circuit elements, thereby improving the overall performance of the semiconductor device 100. The BDI 122A can isolate the top portion of the BSCA 116 from the gate region 118.

By isolating each transistor, BDI 122A helps to prevent the failure of one transistor from affecting the others. This can improve the overall reliability of the device. Additionally, the BDI 122A allows for more flexibility in device design, as it allows each transistor in the stack to be accessed and controlled independently. This can be beneficial in a variety of applications where specific transistors may need to be activated or deactivated based on certain conditions. In some embodiments, the BDI 122A can help decrease the parasitic capacitance associated with the transistor, which can lead to faster switching times and improved performance.

The MDI 122B, similar to the BDI 122A, can electrically isolate individual components in the semiconductor device 100, and provide electrical isolation between each of the FETs in the stacked FET. That is, the MDI 122B can ensure that the operation of one component does not interfere with the operation of the others. By using a dielectric layer, which is an insulating layer that does not conduct electricity, the MDI 122B effectively prevents electrical crosstalk between the transistors and allows each one to operate independently. Further, by electrically isolating each transistor from the other, the MDI 122B can reduce the potential for crosstalk, which is the unwanted transfer of signals between circuit elements, thereby improving the overall performance of the semiconductor device 100.

By isolating each transistor, MDI 122B helps to prevent the failure of one transistor from affecting the others. This can improve the overall reliability of the device. Additionally, the MDI 122B allows for more flexibility in device design, as it allows each transistor in the stack to be accessed and controlled independently. This can be beneficial in a variety of applications where specific transistors may need to be activated or deactivated based on certain conditions. In some embodiments, the MDI 122B can help decrease the parasitic capacitance associated with the transistor, which can lead to faster switching times and improved performance.

In various embodiments, the bottom contact is connected to the BEOL 128 via the M1 track 134. In an embodiment, the M1 track 134 can be used to connect various elements of the semiconductor device 100 to the BEOL 128. The STI 126 helps prevent electrical crosstalk and interference between adjacent components, allowing for the proper functioning of integrated circuits. In various embodiments, the gate region 118, and the gate caps 138, along with the gate spacers (not shown), can define the region where current flows between the top source/drain region 110A and the bottom source/drain region 110B.

Example Processes for Semiconductor Device with Insulated Backside Contact Structures

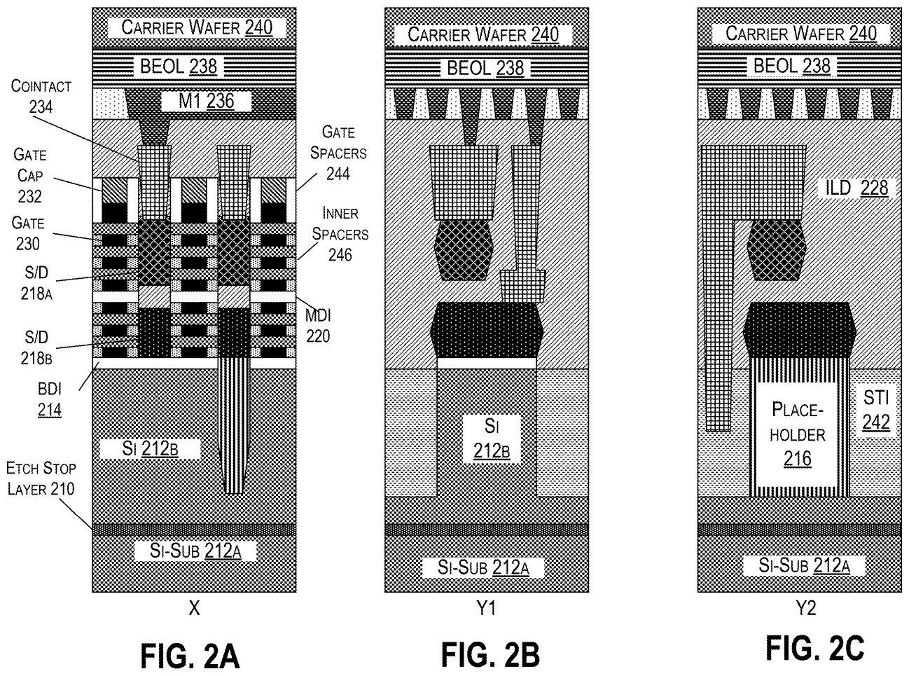

With the foregoing description of an example semiconductor device, it may be helpful to discuss an example act of manufacturing the same. To that end, FIGS. 2-13 illustrate various steps in manufacturing a semiconductor device, consistent with illustrative embodiments. As noted above, figures denoted by A, B, and C illustrate acts of fabrication of the semiconductor device 100 from a different point of view (i.e., cross-sections of a device). It is also worth mentioning that the semiconductor device 100 depicted in FIGS. 1A-1C can be the same as the semiconductor device depicted in FIGS. 2-13. For ease of illustration, the fabrication operations depicted therein will be described in the context of forming stacked transistors. The stacked transistors are fabricated to include a bottom transistor and a top transistor. The bottom transistor is fabricated to include a bottom source/drain region, and the top transistor is fabricated to include a top source/drain region.

Reference now is made to FIGS. 2A-2C, which illustrates a semiconductor device after the processing of the front end of line (FEOL), BEOL, and carrier wafer bonding. Once the FEOL processing is performed, the semiconductor can include an etch stop layer 210 between a first substrate, Si-sub, 212A, a second substrate, Si, 212B, a BDI 214, placeholders 216, a bottom source/drain region 218A, a top source/drain region 218B, an MDI, 220, an ILD 228, gate regions 230, gate caps 232, and a plurality of contacts 234, an M1 track 236, BEOL 238, a carrier wafer 240, a STI 242, gate spacers 244, and inner spacers 246.

In the illustrative example depicted in FIGS. 2A-2C, the semiconductor device is depicted as being on silicon as the first substrate, Si-sub 212A, and the second substrate, Si, 212B, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the Si-sub 210A and the Si 210B may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, an etch stop layer 210 is formed over the Si-sub 212A. The etch stop layer 210 can be a thin layer of material incorporated into the structure of the semiconductor device to provide a selective barrier against etching processes, preventing further removal of underlying materials during fabrication. The etch stop layer 210 can enable precise control over the etching depth and help define the desired device dimensions. The etch stop layer 210 can further provide a stopping point for the etching process, ensuring that specific layers or regions are not etched beyond a certain point, leading to accurate patterning and control of critical features. The etch stop layer 210 can create a distinct separation between different layers or components within the device structure, and prevent the undesired etching of underlying layers or materials, enabling the creation of complex, multi-layered structures with well-defined interfaces and boundaries. In some embodiments, the etch stop layer 210 acts as a protective barrier for sensitive or delicate materials to shield such materials from aggressive etchants, preventing damage or degradation during subsequent fabrication steps.

In some embodiments, prior to forming the etch stop layer 210, the Si-sub 212A is prepared by cleaning and removing any impurities or oxide layers. The etch stop layer 210 is deposited onto the Si-sub 212A using techniques such as epitaxial growth, chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 210 can then be selectively etched, stopping at a predetermined depth, while protecting the underlying layers. After the etching process, the remaining photoresist can be removed through stripping techniques. While in some embodiments, SiGe is used to form the etch stop layer 210, in some embodiments, silicon nitride (SiN) or silicon oxynitride (SiON) can be used as the etch stop layer 210. In some embodiments, Si 212B is epitaxially grown over the etch stop layer 210.

In some embodiments, a placeholder 216 can be epitaxially grown. The use of placeholder 216 can provide more flexibility in the fabrication process, allowing for the creation of complex geometries or the integration of different types of materials.

In some embodiments, the semiconductor device can include nanosheets. The nanosheets (e.g., nanosheet gates, not shown) can be formed by alternating layers of Si and SiGe (not shown), in which the sidewalls of the SiGe layers are indented and covered by the inner spacers 246. The SiGe layers can subsequently be removed and replaced with gate region materials.

The gate spacers 244 can be thin insulating layers or materials placed on the sidewalls of the gate regions 230 and the gate caps 232. The gate spacers 244 can help control the effective channel length of the semiconductor device. In various embodiments, the gate regions 230, and the gate caps 232, along with the gate spacers 244, can define the region where current flows between the bottom source/drain region 218A and the top source/drain region 218B.

In some embodiments, the gate spacers 244 can function as insulating layers between the gate regions 230 and the bottom source/drain region 218A and the top source/drain region 218B. That is, the gate spacers 244 can help prevent current leakage or short circuits between gate regions 230 and the bottom source/drain region 218A and the top source/drain region 218B. Such isolation can help maintain the integrity of the semiconductor device's electrical operation and prevent unintended current flow that could negatively impact the performance of the semiconductor device and reliability.

In further embodiments, the gate spacers 244 can be utilized to modulate the overlapping capacitance between the gate regions 230 and the bottom source/drain region 218A, and the top source/drain region 218B. Overlapping capacitance can affect the semiconductor device's electrical characteristics, such as threshold voltage and switching behavior. Thus, by adjusting the thickness and material properties of the gate spacers 244, the overlapping capacitance can be optimized, which can allow for better control and modulation of the semiconductor device's behavior.

In several embodiments, the gate spacers 244 can help mitigate the short-channel effects by physically separating the gate regions 230 from the bottom source/drain region 218A and the top source/drain region 218B. To that end, the gate spacers 244 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability. In some embodiments, the bottom source/drain region 218A and the top source/drain region 218B are isolated from the gate caps 232 by the gate spacers 244.

In an embodiment, the gate spacers 244 can serve as barriers that prevent the lateral diffusion of dopant atoms from the bottom source/drain region 218A and the top source/drain region 218B, into the channel region during the doping process. Such diffusion can alter the channel characteristics and compromise the semiconductor device's performance. By confining the dopant diffusion, the gate spacers 244 can contribute to maintaining the desired semiconductor device's characteristics and electrical behavior.

In some embodiments, the gate spacers 244 can be formed over the sidewalls of the gate regions 230. The gate spacers 244 can be formed by deposition techniques. Alternatively, the gate spacers 244 can be formed by etching or selectively epitaxially growing the gate spacers 244 over the sidewalls of the gate regions 230. In some embodiments, the gate spacers 244 can include SiGe.

In an embodiment, the inner gate spacers 244, similar to the gate spacers 244, can function as insulating layers between the gate regions 230 and the bottom source/drain region 218A and the top source/drain region 218B. In various embodiments, the inner gate spacers 244 can be the same as the gate spacers 244, which are formed over portions of the gate regions 230 confined between the nanosheet gates.

The ILD 228 can be deposited onto the substrate using various techniques such as CVD, spin-on deposition, plasma-enhanced CVD (PECVD), or ALD. In some embodiments, after deposition, planarization techniques are employed to ensure a flat and smooth surface. In an embodiment, chemical mechanical polishing (CMP) can be used to remove excess material and achieve a uniform surface topography. In some embodiments, silicon dioxide (SiO2), or a low-k dielectric, e.g., organosilicates, fluorinated silicates, or porous materials, can be used as ILD 228. Alternatively, polymer-based materials, such as polyimide or polybenzoxazole (PBO), can be used as ILD 228.

The gate caps 232 can be formed over a plurality of gate regions. The sidewalls of the gates can be covered by gate spacers 244 (not shown). Further, the adjacent nanosheets can be separated by inner gate spacers 244. In some embodiments, the gate caps 232 can be made of the same materials as the gate spacers 244 and the inner gate spacers 244.

In some embodiments, the gate region 230 can include a thin layer of gate dielectric and gate metals (not shown). The gate metal can be separated from the gate channel by the gate dielectric, such as SiO2, HfO2, or HfLaOX.

In an embodiment, a plurality of contacts 234 can be formed over the top source/drain regions 218B and the bottom source/drain region 218A. One or more contact of the plurality of contacts 234 can be recessed, after which chemical mechanical polishing (CMP) can be performed.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

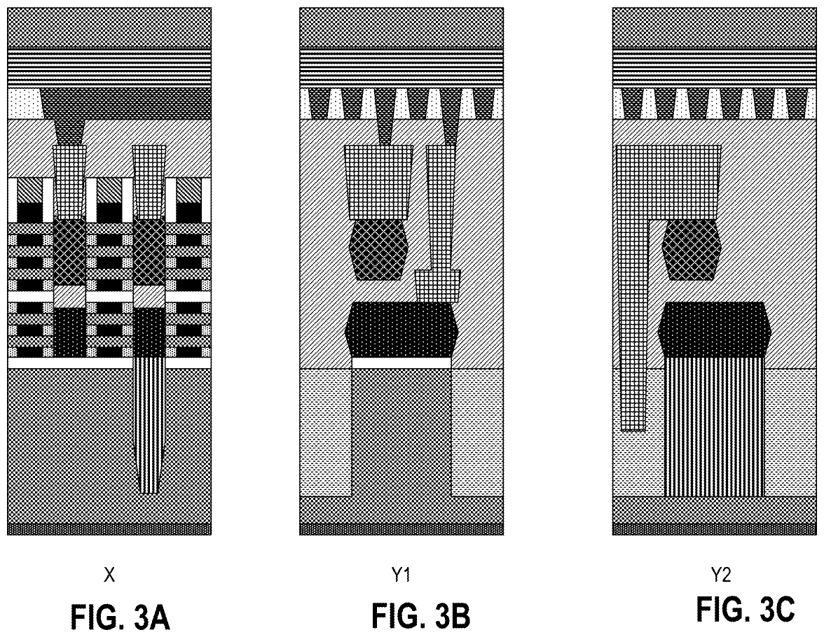

FIGS. 3A-3C illustrate side-views of different cross-sections of a semiconductor device after the removal of the substrate, in accordance with some embodiments. In some embodiments, the wafer is flipped, and the Si-sub is removed. The Si-sub removal process can proceed until reaching the etch stop layer. It should be noted that, for the sake of simplicity, the semiconductor device is not shown as flipped.

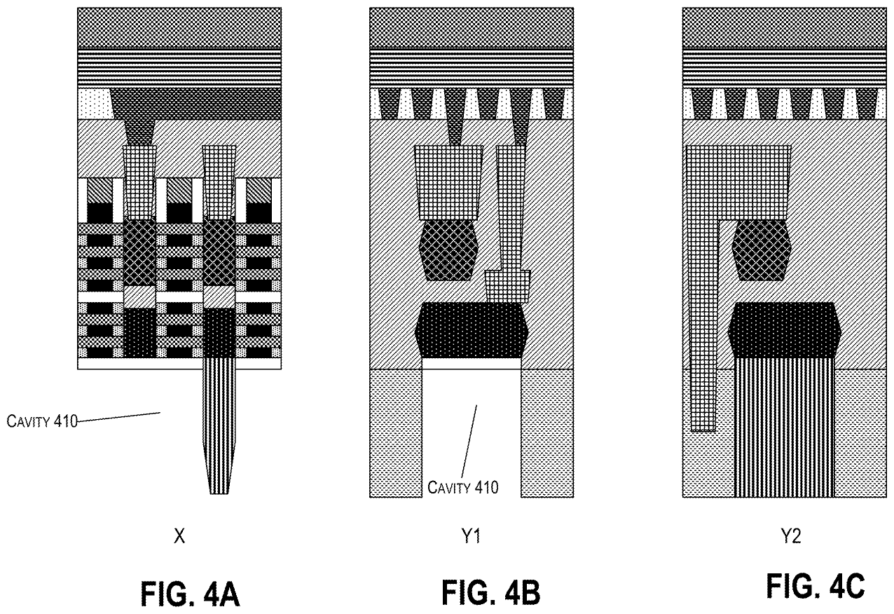

FIGS. 4A-4C illustrate side-views of different cross-sections of a semiconductor device after the removal of the etch stop layer, in accordance with some embodiments. In some embodiments, once the etch stop layer is removed, the remaining Si-sub is also removed. Thus, no etch stop layer or Si-sub is remained. As a result, a first cavity 410 is formed.

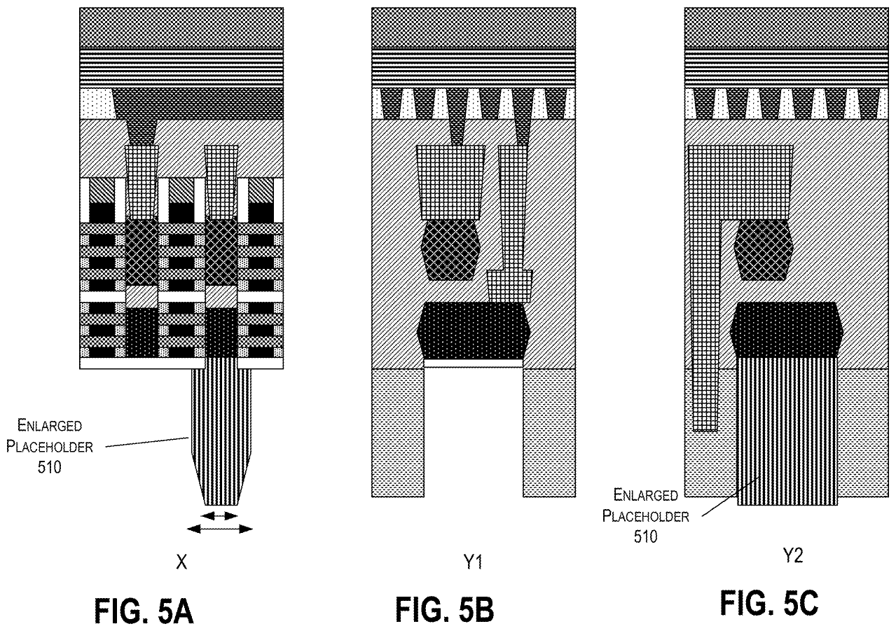

FIGS. 5A-5C illustrate side-views of different cross-sections of a semiconductor device after enlarging the placeholder size, in accordance with some embodiments. In some embodiments, the placeholder is grown conformally to increase the size of the placeholder. It should be noted that, while the size, i.e., dimensions, of the placeholder is increased in the X-cross section, as shown in FIG. 5A, the size, i.e., dimensions, of the placeholder in the Y1-cross section, as shown in FIG. 5B, and the Y2-cross section, as shown in FIG. 5C, remain the same. As a result, the width of the enlarged placeholder 510 in the X-cross section, as shown in FIG. 5A, is substantially larger than the width of the source/drain region above the placeholder, as compared by arrows at the bottom of FIG. 5A.

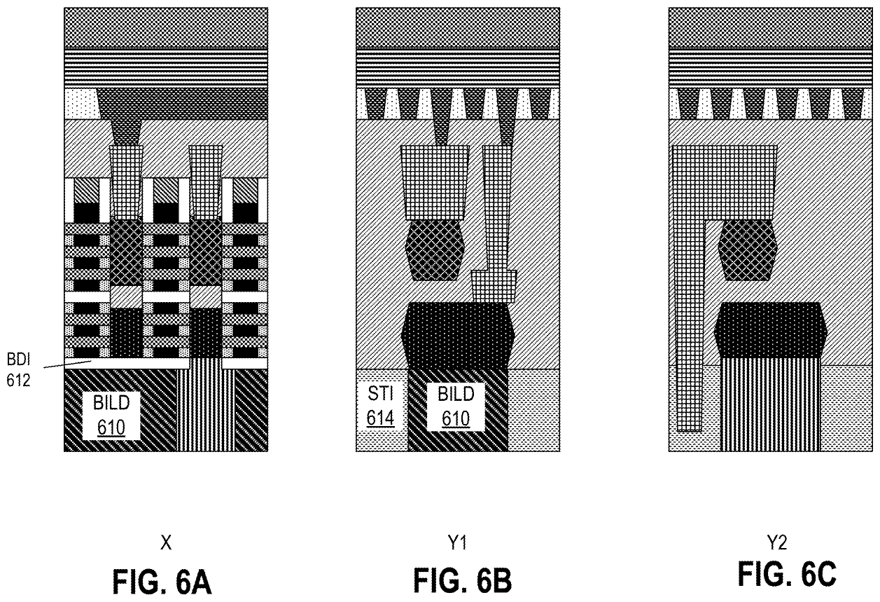

FIGS. 6A-6C illustrate side-views of different cross-sections of a semiconductor device after the formation of BILD 610, in accordance with some embodiments The BILD 610 is formed below the BDI 612, and surrounds the placeholder, and the STI 614. In an embodiment, a chemical mechanical polishing (CMP) process is further processed after the formation of the BILD 610. The BILD 610 can be an insulating material or layer used to isolate and provide electrical insulation between the semiconductor device's active regions and the BSCA, and to prevent unwanted electrical contact between the active regions and the backside contact, ensuring the proper functioning and integrity of the semiconductor device. In various embodiments, the BILD 610 can function as a protective layer, shielding the active regions of the semiconductor device from external contaminants, moisture, and mechanical stress. The BILD 610 can further help prevent physical damage, such as scratches or particle contamination, which could adversely affect semiconductor device performance. Additionally, the BILD 610 can function as a barrier against moisture ingress, which can cause corrosion and degradation of the semiconductor device's components. In some embodiments, the placeholder can be removed so that a recess is formed that exposes the bottom of the first source/drain region.

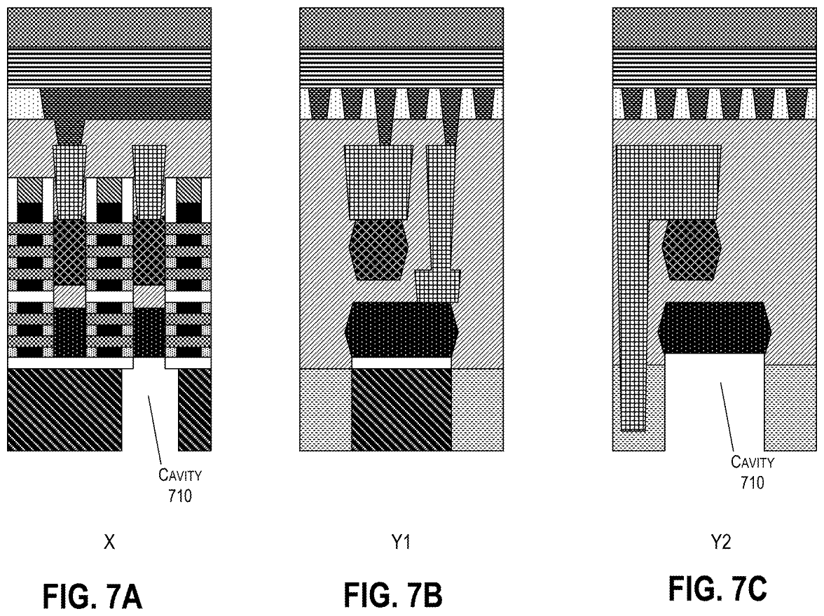

FIGS. 7A-7C illustrate side-views of different cross-sections of a semiconductor device after the removal of the placeholder, in accordance with some embodiment. In some embodiments, the placeholder, i.e., the sacrificial placeholder, is removed, and a cavity 710 within the BILD is formed. The cavity can be formed by a selective reactive ion etching (RIE) technique or selective wet etch process. Generally, RIE is a dry etching process used in semiconductor device fabrication to remove materials from the surface of a substrate selectively. In some embodiments, RIE can involve using reactive ions and plasma to react with and remove specific materials chemically. In an embodiment, the RIE process begins by placing the semiconductor device inside a vacuum chamber. The chamber is then evacuated to create a low-pressure environment.

Reactive gases, comprising a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment. In some embodiments, Radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds, and remove silicon. In various embodiments, the RIE process can be selective, meaning it can mainly affect the target material, i.e., silicon, while leaving other materials, such as masking layers or underlying layers, relatively unaffected. In some embodiments, to achieve selective etching, an etch mask can be applied on the substrate surface prior to the RIE process. The etch mask protects certain regions from etching, allowing the reactive ions to remove the exposed material selectively.

The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is contaminant-free.

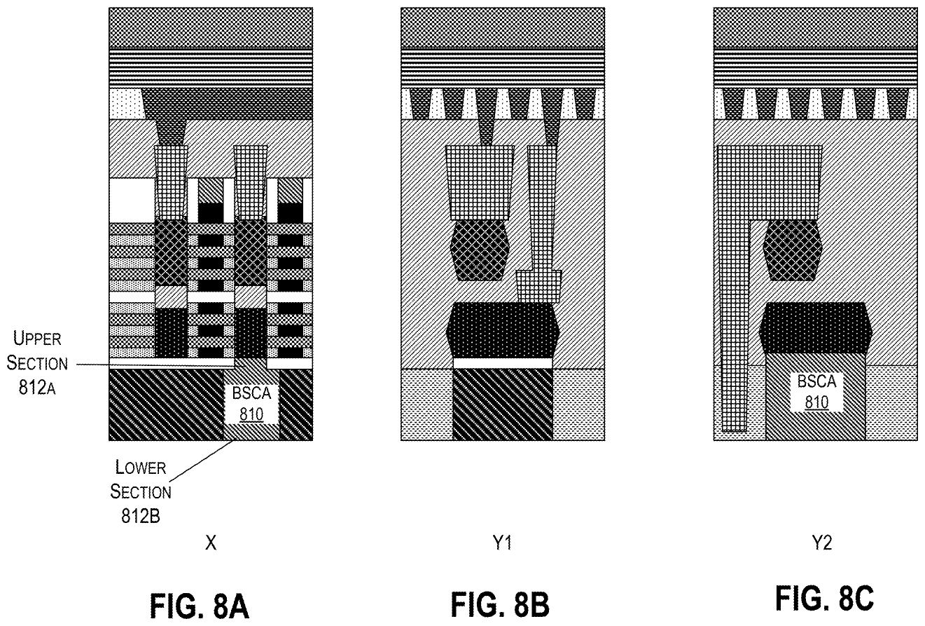

FIGS. 8A-8C illustrate side-views of different cross-sections of a semiconductor device after the formation of the BSCA, in accordance with some embodiments. In an embodiment, the BSCA 810 is formed within the cavity by filling with a metal. Since the placeholder was enlarged in the X-cross section to include a larger width compared to the width of the bottom source/drain region, the BSCA 810 can include a lower section 812A with a larger width and an upper section with a smaller width in the X-cross section 812B. The BSCA metal includes a silicide liner, such as Ti, Ni, NiTi, NiPt, etc., an adhesion metal liner, such as TiN, and low resistance metal fill, such as W, Ru, Co, etc.

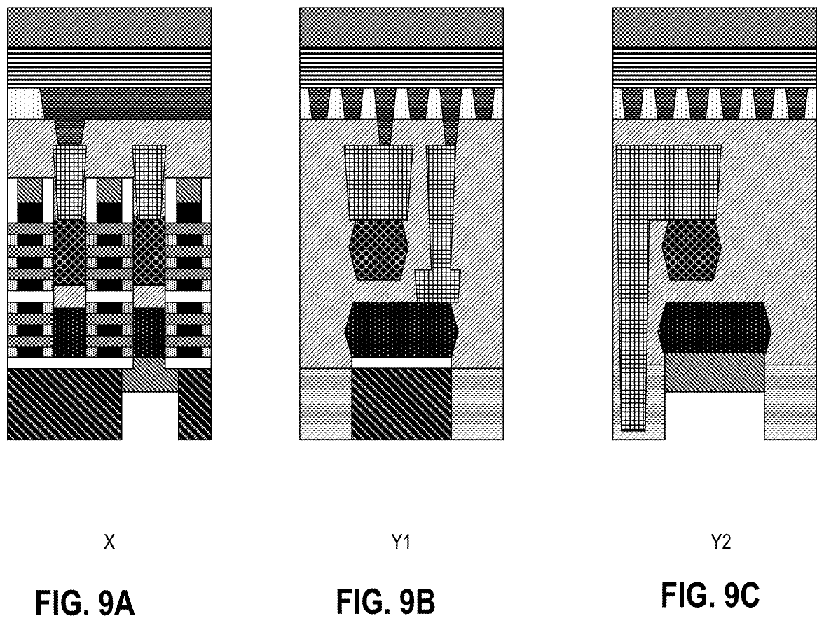

FIGS. 9A-9C illustrate side-views of different cross-sections of a semiconductor device after the recession of the BSCA 810, in accordance with some embodiments. In an embodiment, the BSCA 810 is recessed by removing portions of the lower section.

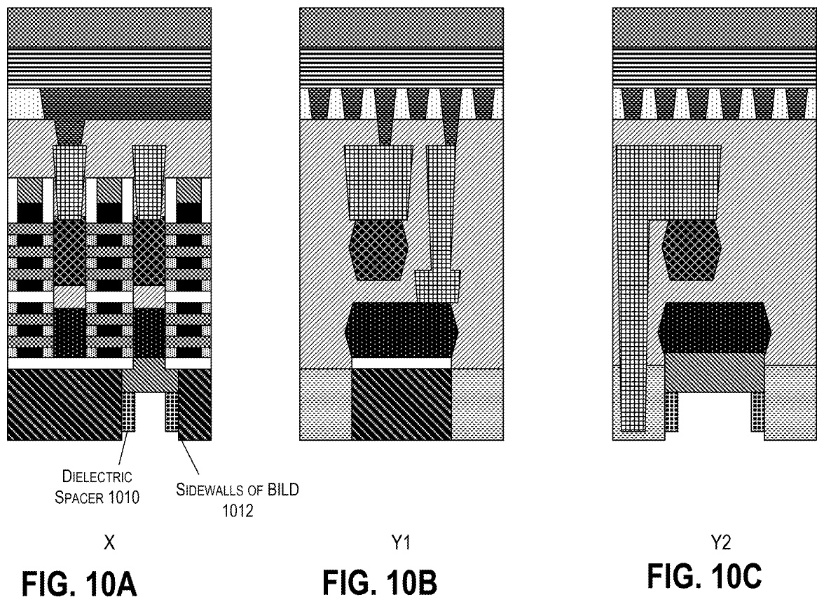

FIGS. 10A-10C illustrate side-views of a semiconductor device after the formation of the dielectric spacer, in accordance with some embodiments. In an embodiment, the dielectric spacer 1010 is formed over portions of the sidewalls 1012 of the BILD.

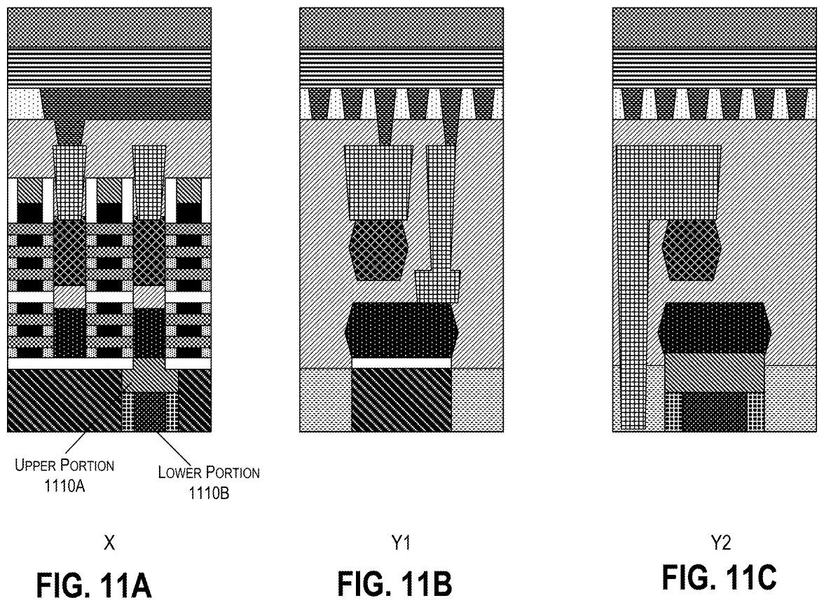

FIGS. 11A-11C illustrate side-views of a semiconductor device after the selective metal growth, in accordance with some embodiments. In an embodiment, a metal is selectively grown within the cavity and between the dielectric spacer and the lower portion of the BSCA. In some embodiments, the selectively grown metal can include the same material as the upper portion and the lower portion of the BSCA. However, in some embodiments, the selectively grown metal can be different from the material used for the upper portion 1110A and the lower portion 1110B of the BSCA. Therefore, the BSCA can have a T-shape profile in the X-cross section, as shown in FIG. 11A. In some embodiments, the lower portion of the BSCA 1110B can include a liner-less metal fill. Alternatively, in some embodiments, the lower portion of the BSCA 1110B can include metal fill with adhesion liner such as TiN.

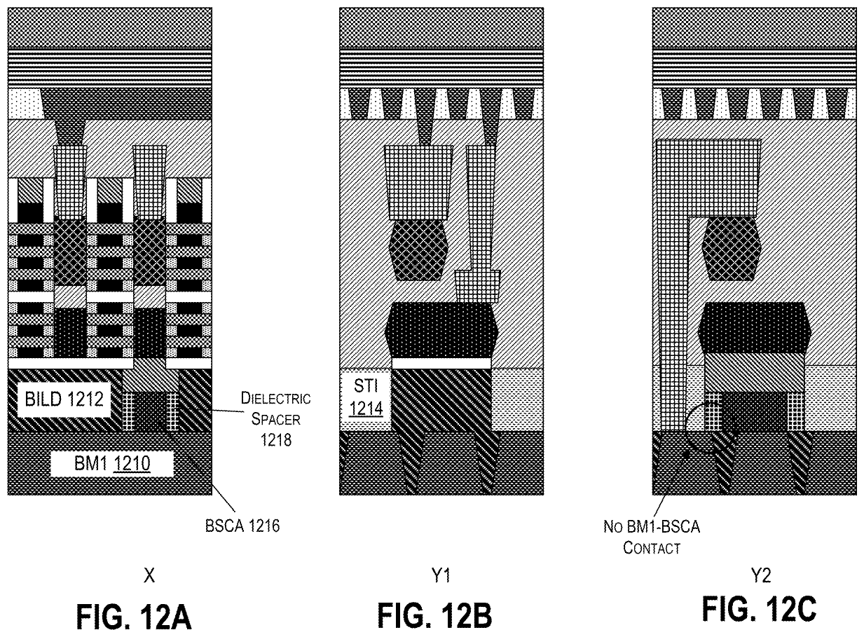

FIGS. 12A-12C illustrate side-views of a semiconductor device after the formation of the backside metal, in accordance with some embodiments. In an embodiment, the backside metal, BM1 1210 is formed below the STI 1214, the BSCA 1216, and the dielectric spacer 1218. In some embodiments, additional BILD 1212 is deposited before the BM1 1210 line patterning. In such embodiments, the BM1 1210 is formed within the BILD 1212. Since the lower portion of the T-shaped BSCA has a smaller width compared to the upper section of the BSCA, the BSCA 1216 is not in direct contact with the portions of the BM1 1210 that are connected to the via. This is shown by an arrow to a highlighted section in FIG. 12C. Further, the dielectric spacer 1218 isolates the BSCA 1216 from direct contact with the portions of the BM1 1210 that are connected to the via. Thus, the BM1 1210-BSCA 1216 shorting problem is avoided.

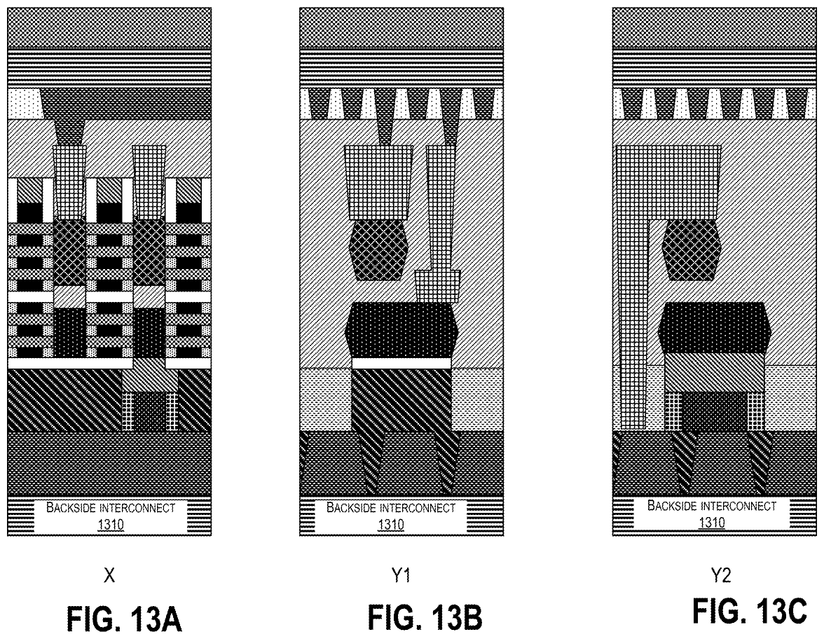

FIGS. 13A-13C illustrate side-views of a semiconductor device after the formation of the backside interconnect, in accordance with some embodiments. In some embodiments, a backside interconnect 1310 is formed below the BM1. The backside interconnect 1310 can be used to connect the semiconductor device to other devices.

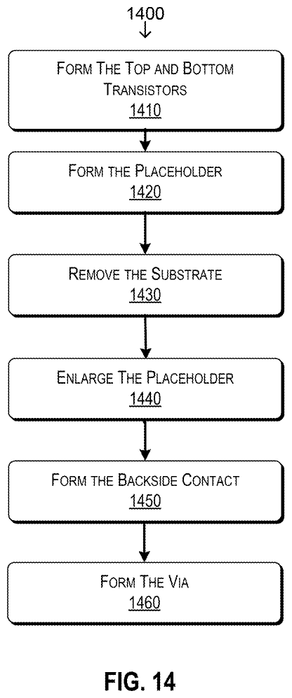

FIG. 14 illustrates a block diagram of method 1400 for forming the semiconductor device, in accordance with some embodiments. Referring to FIG. 14, at block 1410, the top transistor is formed over the bottom transistor.

At block 1420, a placeholder is formed. At block 1430, the substrate is removed. In some embodiments, as shown by block 1440, the placeholder is enlarged by depositing additional placeholder material.

In some embodiments, as shown by block 1450, the backside contact is formed. As shown by block 1460, the via is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or 14 implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a top transistor stacked over a bottom transistor;
a backside contact connected to a source/drain region of the bottom transistor, wherein the backside contact has a T-shape profile; and
a via connecting a source/drain region of the top transistor to a backside power rail (BPR).

2. The semiconductor device of claim 1, wherein the backside contact has the T-shape profile through both a first direction and a second direction, wherein the first direction is orthogonal to the second direction.

3. The semiconductor device of claim 1, further comprising a dielectric spacer over sidewalls of a vertical section of the backside contact.

4. The semiconductor device of claim 3, wherein the dielectric spacer is configured to isolate the backside contact from the BPR.

5. The semiconductor device of claim 1, wherein a top portion of the backside contact is isolated from a gate region by a bottom dielectric isolation (BDI).

6. The semiconductor device of claim 1, wherein a source/drain region of the top transistor is connected to a back end of line (BEOL) through a first contact.

7. The semiconductor device of claim 6, wherein the first contact is in contact with a via.

8. A method for forming a semiconductor device, comprising:
forming a top transistor stacked over a bottom transistor;
forming a sacrificial placeholder below a source/drain region of the bottom transistor;
removing a substrate below the bottom transistor;
depositing additional sacrificial placeholder material to increase dimensions of the sacrificial placeholder in a first direction;
forming a backside contact connected to a source/drain region of the bottom transistor; and
forming a via connecting a source/drain region of the top transistor to a backside power rail (BPR).

9. The method of claim 8, wherein the backside contact has a T-shape profile through both a first direction and a second direction, wherein the first direction is orthogonal to the second direction.

10. The method of claim 8, further comprising forming a dielectric spacer over sidewalls of a vertical section of the backside contact.

11. The method of claim 8, further comprising connecting a source/drain region of the top transistor to the BPR by the via.

12. The method of claim 8, further comprising isolating a top portion of the backside contact from a gate region by a bottom dielectric isolation (BDI).

13. The method of claim 10, further comprising isolating the backside contact from the BPR by the dielectric spacer.

14. The method of claim 8, further comprising connecting a source/drain region of the top transistor to a back end of line (BEOL) through a first contact.

15. The method of claim 14, further comprising connecting a top portion of the via to the first contact.

16. A semiconductor device, comprising a top transistor stacked over a bottom transistor, wherein a backside contact is connected to a source/drain region of the bottom transistor, and wherein the backside contact has a T-shape profile through both a first direction and in a second direction, wherein the first direction is orthogonal to the second direction.

17. The semiconductor device of claim 16, further comprising a dielectric spacer over sidewalls of a vertical section of the backside contact.

18. The semiconductor device of claim 17, further comprising a via connecting a source/drain region of the top transistor to a backside power rail (BPR), wherein the dielectric spacer isolates the backside contact from the BPR.

19. The semiconductor device of claim 16, wherein a top portion of the backside contact is isolated from a gate region by a bottom dielectric isolation (BDI).

20. The semiconductor device of claim 16, wherein the source/drain region of the top transistor is connected to a back end of line (BEOL) through a first contact, and wherein the first contact is in contact with the via.
